(19) United States
(12) Patent Application Publication
(10) Pub. No.: US 2019/0085449 A1
(43) Pub. Date: Mar. 21, 2019

(54) APPARATUS AND METHOD

(71) Applicant: BENEQ OY, Espoo (FI)

(72) Inventor: Markus BOSUND, Espoo (FI)

(21) Appl. No.: 16/083,545

(22) PCT Filed: Mar. 10, 2017
(86) PCT No.: PCT/FI2017/050159

§ 371 Date: Sep. 10, 2018

(30) Foreign Application Priority Data
Mar. 11, 2016 (FI) 20165205

(51) Int. Cl. C23C 16/455

(52) U.S. Cl. CPC C23C 16/45544; C23C 16/52

(57) ABSTRACT

An apparatus for subjecting a surface of a substrate to successive surface reactions of at least a first precursor and a second precursor according to the principles of atomic layer deposition includes a reaction chamber defining a reaction space, one or more gas inlets, one or more gas outlets and a plasma discharge electrode. The apparatus further includes an grounded grid sheet having openings and arranged within the reaction space opposite the plasma discharge electrode.

### FIELD OF THE INVENTION

The present invention relates to an apparatus for subjecting a surface of a substrate to successive surface reactions of at least a first precursor and a second precursor according to the principles of atomic layer deposition, and more particularly to an apparatus according to the preamble of claim 1. The present invention further relates to a method for subjecting a surface of a substrate to successive surface reactions of at least a first precursor and a second precursor according to the principles of atomic layer deposition, and more particularly to a method according to the preamble of claim 13.

### BACKGROUND OF THE INVENTION

Atomic layer deposition (ALD) is conventionally carried out in a reaction chamber under vacuum conditions. One or more substrates are first loaded into the reaction chamber and then vacuum is evacuated into the reaction chamber and the reaction space inside the reaction chamber is heated to process temperature. The atomic layer deposition is then carried out by supplying at least first and second gaseous precursors into the reaction chamber alternatingly and repeatedly for providing a coating layer with desired thickness on the surface of the substrate. A full ALD cycle, in which the first and second precursor are supplied into the reaction chamber comprises: supplying a pulse of first precursor into the reaction chamber, purging the first precursor from the reaction chamber, supplying a pulse of second precursor into the reaction chamber and purging the second precursor from the reaction chamber. Purging precursors may comprise discharging the precursor material from the reaction chamber, supplying purge gas, such as nitrogen, into the reaction chamber and discharging the purge gas. When desired number of ALD cycles and thus a desired coating layer thickness is reached, the vacuum in the reaction chamber is vented and the substrates are unloaded from the reaction chamber. Then the same process is repeated for the next substrates.

ALD process can be modified by applying plasma to the deposition cycle, this is called plasma-enhanced ALD. Plasma may be capacitively created plasma in which two electrodes are placed within a small distance from each other, one of the electrodes is connected to an RF power supply and the other is grounded. Thus plasma is ignited between the electrodes. In plasma mode an electric discharge is subjected to one of the precursors such that active precursor radicals, ions, are formed from the precursor. The active precursor radicals react on the surface of the substrate during an ALD cycle.

Plasma may be created as so called remote plasma in which the active precursor radicals are formed with plasma electrodes far away from the substrate and outside of the reaction chamber. The plasma comprising the active precursor radicals for then conveyed and pulsed into the reaction chamber in a conventional manner of pulsing precursor successively. The disadvantage of remote plasma is that the life time of the active precursor radicals is very limited, typically seconds. When the active precursor radicals are conveyed from distance to the reaction chamber or to the substrate the active precursor radicals tend to lose their electric potential and to be become deactivated. When the active precursor radicals become deactivated they do not react on the surface of the substrate and thus the efficiency of the ALD coating process is decreased.

Alternatively plasma may be created as so called direct plasma in which the substrate is arranged between the plasma electrodes and the plasma discharge is arced through the substrate. In this case the plasma is ignited in the reaction space between the plasma discharge electrode coupled to RF power supply and the substrate. This enables forming of the active precursor radicals close to the substrate such that the active precursor radicals do not become deactivated before reaching the substrate. However, the disadvantage of the direct plasma is that arcing in the reaction chamber cause production of solid particles which are then deposited on the surface of substrate. The solid particles compromise the coating process and decrease the quality of the produced coating due to unwanted particles in the coating.

### BRIEF DESCRIPTION OF THE INVENTION

An object of the present invention is to provide an apparatus and method so as to overcome or at least alleviate the above mentioned disadvantages of the prior art. The objects of the present invention are achieved by an apparatus according to the characterizing portion of claim 1. The objects of the present invention are further achieved by a method according to the characterizing portion of claim 13.

The preferred embodiments of the invention are disclosed in the dependent claims.

The present invention is based on the idea of providing an apparatus for subjecting a surface of a substrate to successive surface reactions of at least a first precursor and a second precursor according to the principles of atomic layer deposition. The apparatus comprises a reaction chamber having wall surfaces defining a reaction space inside the reaction chamber, one or more gas inlets for supplying the at least first precursor and second precursor into the reaction space, one or more gas outlets and a plasma discharge electrode for generating an electric discharge to the reaction space. According to the present invention the apparatus further comprises a grid sheet provided in the reaction space and having openings arranged to pass towards the substrate active precursor radicals generated by the plasma discharge. The grid sheet is connected to ground potential and arranged within the reaction space opposite the plasma discharge electrode. Accordingly the grid sheet is provided inside and within the gas space of the reaction chamber, meaning within the reaction space of the reaction chamber. As the plasma discharge electrode is connected to the voltage source, the grounded grid sheet forms the other electrode for igniting the plasma. Therefore, the plasma is ignited between the plasma discharge electrode and the grid sheet inside the reaction space. The apparatus or the body of the apparatus is also connected to ground potential. In the context of this application term grounded means that for example the body or the grid sheet is electrically connected to ground potential.

In one embodiment of the apparatus the plasma discharge electrode is arranged in connection with a first wall surface of the reaction chamber and the grid sheet is arranged into the reaction space opposite the plasma discharge electrode and at a first distance from the first wall surface and at a second distance from a wall surface opposite the first wall surface or from the substrate. Accordingly, the plasma is ignited inside the reaction space and between the grid sheet and the first wall surface. The produced active precursor radicals may be passed through the openings in the grid sheet into the reaction space between the wall surface opposite the first wall surface and the grid sheet or between substrate and grid sheet. Thus the plasma is formed inside the reaction space and close to the surface of the substrate.

In another embodiment the one or more gas inlets are arranged to supply the at least first precursor and second precursor on both sides of the grid sheet. The precursors may thus flow through the reaction space between the plasma discharge electrode and the substrate or the first wall surface and the wall surface opposite the first wall surface and the plasma can be ignited at desired intervals. This enables supplying all the precursors from one or more common gas inlets. Furthermore, this arrangement enables supplying the first precursors continuously and the second precursor in pulsed manner. The first precursor reacts with the second precursor only when it is activated using plasma discharge in the reaction chamber.

The present invention is further based on the idea of providing a method for subjecting a surface of a substrate to successive surface reactions of at least a first precursor and a second precursor according to the principles of atomic layer deposition in a reaction chamber having wall surfaces defining a reaction space inside the reaction chamber, the reaction chamber further comprising a plasma discharge electrode for generating an electric discharge to the reaction space. The method comprises arranging the substrate into the reaction chamber opposite the plasma discharge electrode, supplying the at least first precursor and second precursor into the reaction space via one or more gas inlets and discharging the at least first precursor and second precursor from the reaction space via one or more gas outlets. The present invention further comprises supplying the at least first precursor and second precursor into the reaction space having an grounded grid sheet provided within the reaction space between the plasma discharge electrode and the substrate, the grid sheet having openings and being arranged opposite the plasma discharge electrode, generating plasma discharge with the plasma discharge electrode in the reaction space between the plasma discharge electrode and the grid sheet for forming active precursor radicals from the first precursor and passing at least a portion of the active precursor radicals through the openings in the grid sheet into the reaction space between the substrate and grid sheet. The method of the present invention allows production active precursor radicals close to the surface of the substrate using plasma discharge inside the reaction chamber between the plasma discharge electrode and the substrate.

In one embodiment of the present invention the method comprises supplying the at least first precursor and second precursor into the reaction space of the reaction chamber on both sides of an grounded grid sheet, the plasma discharge electrode being arranged in connection with a first wall surface of the reaction chamber and the grid sheet being arranged into the reaction space between and opposite the plasma discharge electrode and the substrate at a first distance from the first wall surface and at a second distance from the substrate. Therefore, the grid sheet is provided within the gas space of the reaction chamber and the precursor gases flow pass the grid sheet on both sides of the grid sheet, but plasma is ignited and active precursor radicals formed only between the plasma discharge electrode and the grid sheet or between the first wall surface and the grid sheet.

In one embodiment of the present invention the reaction chamber is a cross flow reaction chamber in which the one or more gas inlets and the one or more gas outlets are provided on opposite sides of the reaction space for forming a cross flow reaction chamber in which the at least first precursor and second precursor flow through the reaction space from the one or more gas inlets to the one or more gas outlets.

The present invention does not provide remote plasma in which the active precursor radicals are formed outside the reaction space using plasma discharge and then conveyed into the reaction chamber. The present invention does not either provide direct plasma in which the plasma is arced through the substrate inside the reaction chamber. The present invention provides proximity plasma in which the plasma is ignited inside the reaction chamber close to the substrate but not through the substrate. The present invention provides solution in which a plasma zone is formed into the reaction space inside the reaction chamber close to the surface of the substrate using a grounded grid sheet having openings going through the grid plate. The reaction chamber further comprises a reaction zone inside the reaction space on opposite side of the grid plate in which reaction zone the precursors react on the surface of the substrate. Accordingly, active precursor radicals are formed using plasma inside the reaction chamber and thus the deactivation of active precursor radicals before they reach the substrate is minimized. Furthermore, formation of particles due to arcing the plasma through the substrate inside the reaction chamber is avoided. Furthermore, as the grid sheet is provided within the reaction space the formation of active precursor radicals may be controlled only by controlling the power supply to the plasma discharge electrode and there is no need to pulse supply of the first precursor from which the active precursor radicals are formed using plasma discharge. Therefore, efficient ALD process is achieved with god coating quality.

### BRIEF DESCRIPTION OF THE DRAWINGS

In the following the invention will be described in greater detail by means of preferred embodiments with reference to the accompanying drawings, in which

FIG. 1 shows schematically one embodiment of the apparatus according to the present invention;

FIG. 2 shows schematically a top view of one embodiment of the reaction chamber according to the present invention;

FIG. 3 shows schematically one embodiment of the grid sheet;

FIG. 4 shows schematically a side view of one embodiment of the reaction chamber; and

FIG. 5 shows the reaction chamber of FIG. 4 in which location of the grid sheet is adjusted.

### DETAILED DESCRIPTION OF THE INVENTION

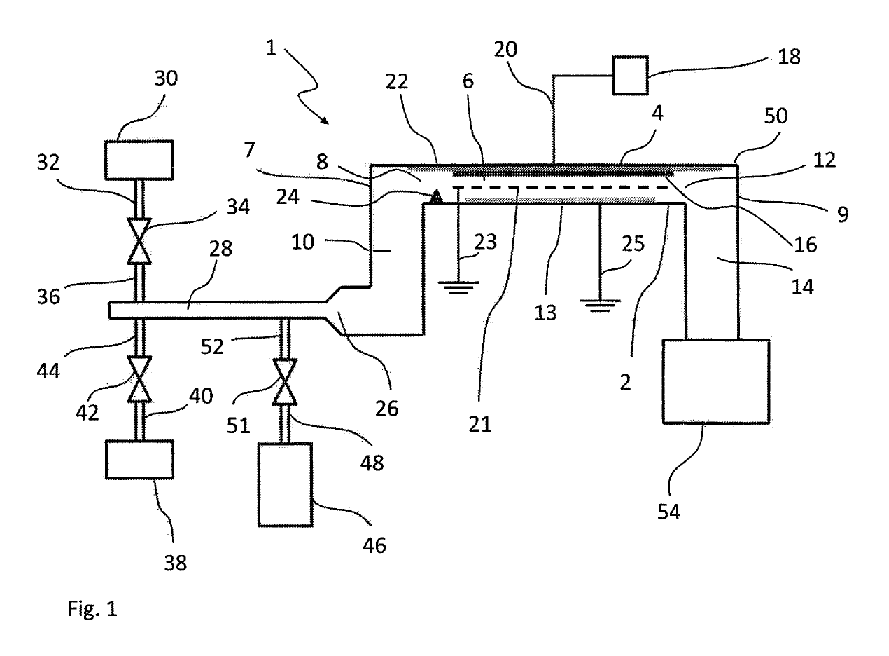

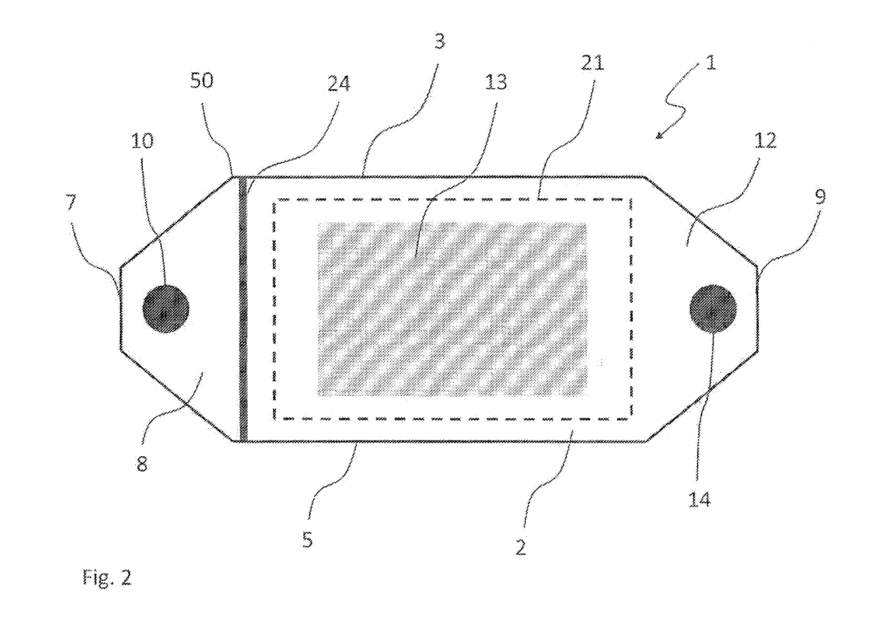

FIG. 1 is shows an apparatus 1, an ALD coating apparatus, for subjecting a surface of a substrate to successive surface reactions of at least a first precursor and a second precursor according to the principles of atomic layer deposition. The apparatus comprises a reaction chamber 50 having wall surfaces 2, 4 defining a reaction space 6 inside the reaction chamber 50. The reaction chamber may be connected to ground potential 25. One embodiment of the reaction chamber 50 is shown in FIG. 2. The reaction chamber 50 comprises one or more gas inlets 8 for supplying at least a first precursor and a second precursor into the reaction space 6 and one or more gas outlets 12 for discharging gases, such as the first and second precursor, from the reaction space 6. The one or more gas inlets 8 and the one or more gas outlets 12 are provided as opening open to the reaction space 6. The apparatus or a body of the apparatus is also connected to ground potential.

The reaction chamber 50 is arranged to receive one or more substrates 13 which are subjected to the at least first and second precursors in the reaction space 6 of the reaction chamber 50. The apparatus may comprise a separate substrate support to which the one or more substrates 13 are supported in the reaction chamber 50 or alternatively one of the side surfaces 2 may be arranged to support substrate 13 such that the substrate 13 placed on the side surface 2.

The apparatus 1 further comprises a precursor supply system. The precursor supply system comprises a first precursor source 38, a second precursor source 46 and a purge gas source 30. The first and second precursor sources 38, 46 and the purge gas source may be gas container, gas bottles or the like. The first precursor source 38 is connected to a gas line 28 via a first precursor conduit 40, 44. The first precursor conduit 40, 44 may be provided with a first precursor supply valve 42 for controlling the first precursor supply from the first precursor source 38. The second precursor source 46 is connected to the gas line 28 via a second precursor conduit 48, 52. The second precursor conduit 48, 52 may be provided with a second precursor supply valve 51 for controlling the second precursor supply from the second precursor source 46. The purge gas source 30 is connected to the gas line 28 via a purge gas conduit 32, 36. The purge gas conduit 32, 36 may be provided with a purge gas supply valve 34 for controlling the purge gas supply from the purge gas source 30. The valves 34, 42, 51 may be any kind of commonly known valves such as shut-off valves for opening and closing the conduits 32, 36, 40, 44, 48, 52 or adjustable valve for adjusting the flow from the sources 30, 38, 46. It should be noted that the purge gas source 30 and relating purge gas conduit 32, 36 and purge gas valve 34 may be omitted in some embodiments.

The gas line 28 to which the first and second precursor source 38, 46 and the purge gas source 30 are connected is further connected to a supply conduit 10 via an expansion 26. The supply conduit 10 further extends to the one or more gas inlets 8. In the embodiment of FIG. 1 the first and second precursor sources 38, 46 as well as the purge gas source 30 are in fluid connection with the one or more gas inlets 8 such that the both first and second precursor, and also purge, are supplied into the reaction chamber 50 via the same common gas inlets 8. Accordingly there are no separate gas inlets or supply conduits for different precursors or purge gas, but the first precursor conduit 40, 44 and the second precursor conduit 48, 52 are arranged in fluid connection with the one or more gas inlets 8 for supplying both the first and second precursor into the reaction space 6 via the one or more gas inlets 8.

In an alternative embodiment the apparatus may comprise one or more first gas inlets for supplying the first precursor into the reaction space 6 and one or more second gas inlets for supplying the second precursor into the reaction space 6. Thus the first precursor conduit 40, 44 or the first precursor source 38 is connected to the one or more first gas inlets for supplying only the first precursor into the reaction space 6 via the one or more first gas inlets. The second precursor conduit 48, 52 or the second precursor source 46 is connected to the one or more second gas inlets for supplying only the second precursor into the reaction space 6 via the one or more second gas inlets. In this case the first and second precursors are supplied via separate gas inlets and separate supply conduits into the reaction space 6. Furthermore, the purge gas may also be supplied via separate purge gas inlet and purge gas supply conduit or alternatively via the one or more first or second gas inlets.

The apparatus 1 may further comprise a gas distributor 24 provided in connection with the one or more gas inlets 8 are downstream of the one or more gas inlets 8. The gas distributor 24 may be gas restraint or protruding part protruding from the wall surface of the reaction chamber or the one or more gas inlets 8. The gas distributor creates turbulence and enhances distribution of the gases into the reaction space 6. In the embodiment of FIG. 1 the gas distributor 24 extends transversely to the flow and/or supply direction of the precursors and protrudes from the second wall surface 4, the bottom surface of the reaction chamber 50.

The apparatus 1 further comprises a discharge conduit 14 connected to the one or more gas outlets 12 for discharging the gases from the reaction chamber 50. The discharge conduit 14 may be further connected to a discharge unit 54, which may comprise a vacuum pump, discharge gas container and/or a gas cleaning device.

As shown in FIG. 1 the one or more gas inlets 8 and the one or more gas outlets 12 are provided on opposite sides of the reaction space 6 for forming a cross flow reaction chamber 50 in which the at least first precursor and second precursor flow through the reaction space 6 from the one or more gas inlets 8 to the one or more gas outlets 12. In the embodiment of FIG. 1 the one or more gas outlets 12 and the one or more gas inlets 8 are provided on opposite side wall surfaces of the reaction chamber 50.

In one embodiment the one or more gas outlets 12 may be provided opposite the one or more gas inlets 8 for forming a cross flow reaction chamber 50 in which the at least first precursor and second precursor flow linearly through the reaction space 6 from the one or more gas inlets 8 to the one or more gas outlets 12.

In FIG. 1 it is shown a side view of the reaction chamber comprising a first wall surface 4, the top surface of the reaction chamber 50, and the second wall surface 2, the bottom surface of the reaction chamber 50. FIG. 2 shows a top view of one embodiment of the reaction chamber 50 having thirds wall surface 7 and opposing fourth wall surface 9. The third and fourth wall surfaces 7, 9 form the end wall surfaces of the reaction chamber 50. The reaction chamber 50 further comprises opposing fifth and sixth wall surfaces 3, 5 forming the side wall surfaces of the reaction chamber and extending between the end side surfaces 7, 9. The first and second wall surfaces 4, 2 extend between the third and fourth wall surfaces 7, 9 and fifth and sixth wall surfaces 3, 5.

In one embodiment the one or more gas inlets 8 are provided to or in connection with the third wall surface 7 of the reaction chamber 50 and the one or more gas outlets 12 are provided to or in connection with the fourth wall surface 9 of the reaction chamber 50 opposite the third wall surface 7 for forming a cross flow reaction chamber 50 in which the at least first precursor and second precursor flow through the reaction space 6 from the one or more gas inlets 8 to the one or more gas outlets 12. In one embodiment the precursors may thus flow as a side flow, preferably substantially horizontally, through the reaction space 6.

Arranging the one or more gas inlets 8 and the one or more gas outlets opposite to each other and forming cross flow ALD reactor, as described above, a simple construction and efficient gas supply and discharge may be achieved. Thus the ALD cycle time may be decreased and the required coating time decreased.

The apparatus 1 further comprises a plasma discharge electrode 16 for generating an electric discharge to the reaction space 6, as shown in FIG. 1. The plasma discharge electrode 16 is connected to a RF voltage supply 18 or power source via voltage supply line 20 for inducing voltage to the plasma discharge electrode in order to generate electric discharge to the reaction space 6. The plasma discharge electrode 16 may be metal plate or the like, such as an aluminium plate. The plasma discharge electrode 16 is preferably arranged over the substrate support or the substrate 13 such that the plasma may be ignited above the substrate 13. An insulator 22 is arranged between the wall surface 4 of the reaction chamber 50 and the plasma discharge electrode 16 for separating the plasma discharge electrode 16 electrically from the reaction chamber 50.

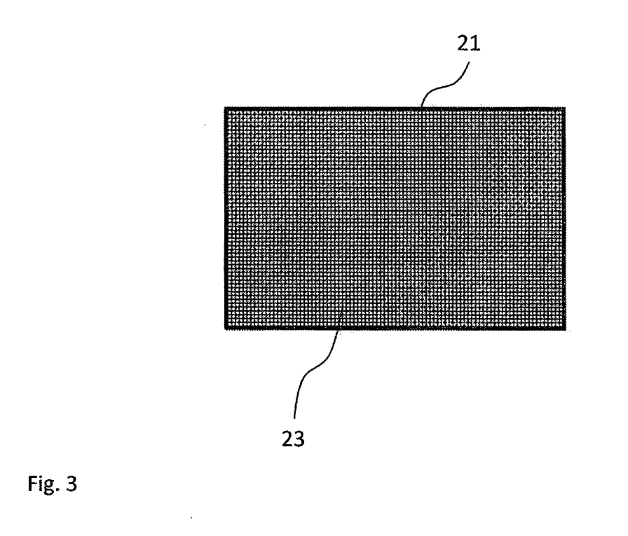

The apparatus 1 further comprises a grid sheet 21 having openings 23 and provided in the reaction space 6. The grid sheet 21 is made of electrically conductive material, for example metal. The grid sheet 21 may be a metal plate comprising openings going through the grid sheet 21 or it may be a metal mesh or the like comprising openings 23 and formed for example from metal wires, as shown in FIG. 3.

The openings 23 may be circular, elliptical, triangular, rectangular polygonal or of any other well know geometrical shape. The size of the opening may be arranged to be such that the diameter or diagonal of the openings 23 is between 0.1 mm to 4 mm, preferably 0.2 mm-3 mm. Therefore, in an embedment is which the openings are circular the diameter of the openings 23 may be 0.1 mm to 4 mm, preferably 0, mm-3 mm. On the other hand when the openings 23 have square shape, the length of a side may be 0.1 mm to 4 mm, preferably 0.2 mm-3 mm.

The grid sheet 21 is connected to ground potential 23 and arranged within the reaction space 6 opposite the plasma discharge electrode 16, as shown in FIG. 1. The term grounded means that the grid sheet is electrically connected to ground potential. In one embodiment the size and shape of the grid sheet 21 substantially corresponds the size and shape of the plasma discharge electrode 16, or the grid sheet may also have larger dimensions than the plasma discharge electrode 16. Accordingly the grid sheet 21 forms the counter electrode for the plasma discharge electrode 16, or the second electrode of the plasma device, such that the plasma is ignited between the plasma discharge electrode 16 and the grid sheet 21 inside reaction space 6.

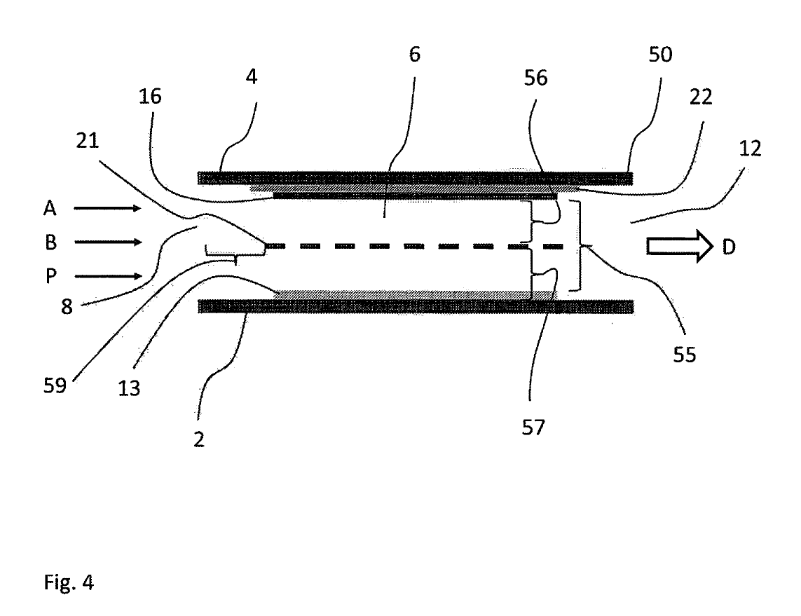

In the embodiment of FIG. 1 the plasma discharge electrode 16 is arranged in connection with the first wall surface 4, top wall surface 4, of the reaction chamber 50 and the grid sheet 21 is arranged into the reaction space 6 opposite the plasma discharge electrode 16. In one embodiment the plasma discharge electrode 16 may form at least part of the first wall surface 4. FIG. 4 shows one embodiment of the reaction chamber 50 and the plasma device in more detail. As shown in FIG. 4 the grid sheet 21 is arranged and placed into the gas space and within the reaction space 6. This means that the grid sheet 21 is arranged between or inside the height 55 of the reaction space 6. Thus the grid sheet 21 is arranged at a first distance 56 from the first wall surface 4, or the plasma discharge electrode 16 and further at a second distance 57 from the wall surface 2 opposite the first wall surface 4, or the substrate support or the substrate 13. Accordingly there is first gap 56 between the first wall surface 4 or the plasma discharge electrode 16 and the grid sheet 21 and a second gap 57 between the grid sheet 21 and the second wall surface 2, the substrate support or the substrate 13. The reaction space 6 is an undivided reaction space and the grid sheet 21 is provided as grate through which the at least first precursor and second precursor, and possibly also purge gas can flow. The undivided reaction space means that all precursor gases are supplied to the whole reaction space 6 and the reaction space 6 has a one uniform volume.

In one embodiment the apparatus 1 comprises a substrate support (not shown), preferably opposite the plasma discharge electrode 16 and the grid sheet 21 for supporting the substrate 13 in the reaction chamber 50. In an alternative embodiment the second wall surface 2 opposite the first wall surface 4, or plasma discharge electrode 16 or the grid sheet 21, is provided as a substrate support for supporting the substrate 13 in the reaction chamber 50.

In one embodiment the grid sheet 21 is arranged opposite the plasma discharge electrode 16 and at the first distance 56 from the plasma discharge electrode 16 and/or opposite the substrate support and at the secand distance from the substrate support. In an alternative the substrate support is arranged opposite the plasma discharge electrode 16, the grid sheet 21 is arranged opposite the plasma discharge electrode 16 at the first distance 56 from the plasma discharge electrode 16, and the grid sheet 21 is arranged opposite the substrate support at the second distance 57 from the substrate support.

The one or more gas inlets 8 are arranged to supply the at least first precursor A and second precursor B, and possibly also purge gas P, into the reaction space 6 such that the at least first precursor A and second precursor B, and possibly also purge gas P are distributed to the whole reaction space 6. Therefore, the one or more gas inlets 8 are arranged to supply the at least first precursor A and second precursor B, and possibly also purge gas P, into the reaction space 6 on both sides of the grid sheet 21, meaning to the first gap 56 between the first wall surface 4 or the plasma discharge electrode 16 and the grid sheet 21 and to the second gap 57 between the grid sheet 21 and the second wall surface 2, the substrate support or the substrate 13.

According to the above mentioned, when the voltage is induced to the plasma discharge electrode 16 plasma is ignited between the plasma discharge electrode 16 and the grid sheet 21. This first gap 56 thus forms a plasma zone inside the reaction space 6. Therefore, active precursor radicals are formed in the first gap 56 between the first wall surface 4 or the plasma discharge electrode 16 and the grid sheet 21 and the formed active precursor radicals may flow through the openings 23 of the grid sheet 21 to the second gap 57 between the grid sheet 21 and the second wall surface 2, the substrate support or the substrate 13. The second gap 57 thus forms a reaction zone inside the reaction space 6 on opposite side of the grid sheet 21 in which reaction zone the precursors react on the surface of the substrate 13.

As shown in FIG. 4, the first and second precursor A, B not reacted on the surface of the substrate 13 and the possible purge gas P are discharged as discharge gases D from the reaction space 6 via the one or more gas outlets 12.

In one embodiment of the present invention, as shown in FIGS. 1 and 4, the one or more gas inlets 8 are provided to the third wall surface 7, or in connection with the same, of the reaction chamber 50 adjacent the first wall surface 4 provided with the plasma discharge electrode 16 such that the at least first precursor A and second precursor B pass the plasma discharge electrode 16 when flowing from the one or more gas inlets 8 to the one or more gas outlets 12.

In another embodiment the one or more gas inlets 8 are provided to the third wall surface 7, or in connection with the same, of the reaction chamber 50, the one more gas outlets 12 are provided to the fourth wall surface 9, or in connection with the same, opposite the third wall surface 7. The first wall surface 4 of the reaction chamber 50 provided with the plasma discharge electrode 16 is adjacent the third wall surface 7 and the fourth wall surface 9 such that the at least first precursor A and second precursor B pass the plasma discharge electrode 16 when flowing from the one or more gas inlets 8 to the one or more gas outlets 12.

In yet another embodiment the one or more gas inlets 8 are provided to the third wall surface 7, or in connection with the same, of the reaction chamber 50, the one more gas outlets 12 are provided to the fourth wall surface 9 opposite the third wall surface 7. The substrate support 2 is provided in connection with the second wall surface 2 opposite the first wall surface 4. The first wall surface 4 of the reaction chamber 50 is adjacent the third wall surface 7 and the fourth wall surface 9 such that the at least first precursor A and second precursor B pass the plasma discharge electrode 16 and flow between the first wall surface 4 and second wall surface 4 when supplied from the one or more gas inlets 8 to the one or more gas outlets 12.

According to the above described the reaction chamber 50 may be arranged such that the one or more gas inlets 8 and the one or more gas outlets 12 are arranged on opposite sides of the reaction space 6 for forming a cross flow reaction chamber 50 and the plasma discharge electrode 16, the grid sheet 21 and the substrate 13 are provided between the one or more gas inlets 8 and the one or more gas outlet 12. The plasma discharge electrode 16, grid sheet 21 and the substrate preferably extend substantially in the direction of the precursor flow inside the reaction space 6, or parallel the precursor flow. In one embodiment the one or more gas outlets 8 is provided to first end wall surface 7 or first side wall surface 3 and the one or more gas outlets 12 to the second end wall surface 9 or second side wall surface 5, as shown in FIG. 2. The plasma discharge electrode 16 is further provided to the top wall surface 4 and the substrate 13 supported on the bottom wall surface 2. The grid sheet 21 is provided between the top wall surface 4 and the bottom wall surface 2. Thus the precursors A, B and the purge gas P may flow from the one or more gas inlets 8 to the one or more gas outlets 12 sideways between the top wall surface 4 and the bottom wall surface 2 and between the discharge electrode 16 and the substrate 13 and between the plasma discharge electrode 16 and the grid sheet 121 and between the grid sheet 21 and the substrate 13.

In one embodiment, as shown for example in FIG. 4, the grid sheet 21 is arranged in front of the one or more gas inlets 8 and to extend from the one or more gas inlets 8 for receiving the at least first precursor A and second precursor B on both sides of the grid sheet 21, meaning to the first gap 56 and the second gap 57.

In an alternative embodiment, as shown for example in FIG. 1, the grid sheet 21 is arranged to extend from the one or more gas inlets 8 for receiving the at least first precursor A and second precursor B on both sides of the grid sheet 21. In other words the grid sheet 21 is arranged to extend from the middle of the one or more gas inlets 8.

The grid sheet 21 may be arranged to extend between the one or more gas inlets 8 and the one or more gas outlets 12 for receiving the at least first precursor and second precursor on both sides of the grid sheet 21. In one embodiment shown in FIG. 4 the grid sheet 21 is arranged at a third distance 59 from the one or more gas inlets 8 and to extend between the one or more gas inlets 8 and the one or more gas outlets 12 for receiving the at least first precursor A and second precursor B on both sides of the grid sheet 21. Accordingly, the precursors A, B are supplied on both sides of the grid sheet 21 via the reaction space 6, as the grid sheet 21 does not extend to the gas inlets 8. In the similar manner the grid sheet 21 may extend to a fourth distance from the gas outlets 12 such that the precursors A, B are discharged from both sides of the grid sheet 21 and via the reaction space 6. Accordingly, the precursors A, B are first supplied into the reaction space 6 and in the reaction space 6 the precursors A, B flow on both sides of the grid sheet 21.

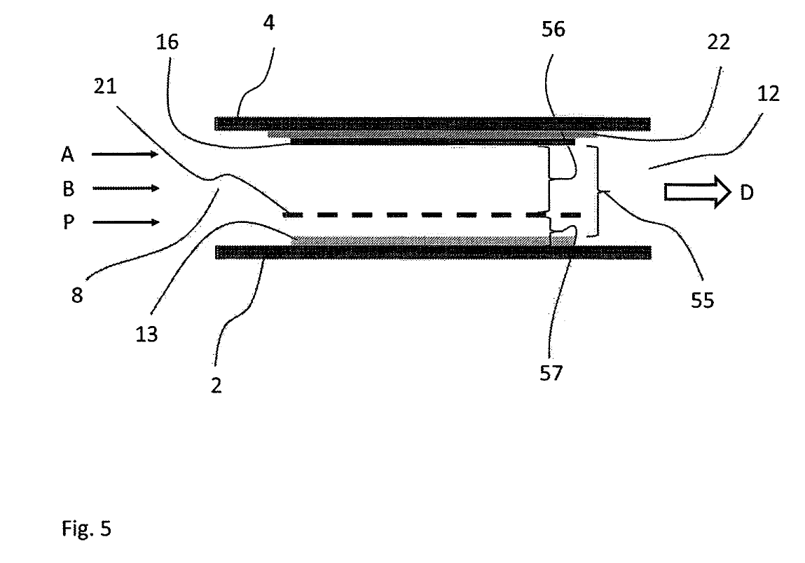

FIGS. 4 and 5 show an alternative embodiment in which the apparatus 1 comprises an adjustment arrangement (not shown) for adjusting the first distance 56 between the grid sheet 21 and the first wall surface 4 or the plasma discharge electrode 16 and/or or for adjusting the second distance 57 between the grid sheet 21 and the second wall surface 2 opposite the first wall surface 4 or the substrate 13 or the substrate support. In an alternative embodiment the apparatus may comprise an adjustment arrangement (not shown) for adjusting the first distance 56 between the grid sheet 21 and the first wall surface 4 and second distance 57 between the grid sheet 21 and second wall surface 2 opposite the first wall surface 4 or the substrate 13 or the substrate support. Accordingly, the adjustment mechanism may be arranged to adjust the height of the plasma zone and the height of the reaction zone in the reaction space 6. FIGS. 4 and 5 show the same reaction chamber, but in FIG. 5 the grid sheet 21 is lowered towards the second wall surface or the substrate 13 such that the plasma zone is provided closer to the substrate 13.

It should be noted that power of plasma discharge and also the pressure inside the reaction chamber 50 affect the shape and size of the plasma discharge. Therefore, the exact placement of the grid sheet 21 is adjusted based on the process parameters. Therefore, the thus first distance between the grid sheet 21 and the first wall surface 4 or the plasma discharge electrode 16 and/or or the second distance 57 between the grid sheet 21 and the second wall surface 2 opposite the first wall surface 4 or the substrate 13 or the substrate support may be adjusted based on the process parameters and power of plasma discharge.

The apparatus 1 may further comprise a precursor system arranged to supply the first precursor A continuously and the second precursor B in pulsed manner into the reaction chamber 50 via the one or more gas inlets 8 into the reaction space 6. Alternatively the precursor system may be arranged to supply the first precursor A and inert purge gas P continuously and the second precursor B in pulsed manner into the reaction chamber 50 via the one or more gas inlets 8 into the reaction space 6.

In one embodiment the precursor system may be arranged to supply the first precursor A continuously and the second precursor B in pulsed manner into the reaction chamber 50 via the one or more gas inlets 8 into the reaction space 6. The precursor system is further arranged to activate the plasma discharge electrode 16 by inducing voltage to the plasma discharge electrode 16 from the RF voltage source 18 between the supply pulses of the second precursor B for forming active precursor radicals from the first precursor A.

In an yet alternative embodiment the precursor system may be arranged to supply the first precursor A and inert purge P gas continuously and the second precursor B in pulsed manner into the reaction chamber 50 via the one or more gas inlets 8 into the reaction space 6. The precursor system is further arranged to active the plasma discharge electrode 16 by inducing voltage to the plasma discharge electrode 16 from the RF voltage source 18 between the supply pulses of the second precursor B for forming active precursor radicals from the first precursor A.

In one embodiment the first precursor A may be oxygen O₂ and the second precursor B trimethylaluminium TMA. The purge gas may be nitrogen N₂. O₂ and TMA do not react together, but when plasma is ignited O₂ form active precursor radicals which react with TMA. Thus the coating process may be controlled by the voltage supply from the RF voltage source 18 to the plasma discharge electrode 16 by turning the voltage supply on and off. Therefore, there is no need pulsing or interrupting the supply of the first precursor A. Thus the first and second precursor A, B may be chosen such that they do not react together until the first precursor A is subjected to plasma for forming active precursor radicals from the first precursor A. Furthermore, this enables supplying the first and second precursor A, B via the common gas inlets 8. This provides a very well controllable and efficient ALD process in which the dead time due to purging different precursors may be avoided.

The active precursor radicals are thus formed in the first gap 56, plasma zone, between the plasma discharge electrode 16 and the grid sheet 21. The formed active precursor radicals are further passed through the opening 23 of the grid sheet 21 to the second gap 57, reaction zone, between the grid sheet 21 and the substrate 13 in which the active precursor radicals react on the surface of the substrate 13.

The present invention further relates to a method for subjecting a surface of a substrate 13 to successive surface reactions of at least a first precursor and a second precursor according to the principles of atomic layer deposition in a reaction chamber 50 having wall surfaces 2, 4, 3, 5, 7, 9 defining a reaction space 6 inside the reaction chamber 50. The reaction chamber 50 further comprises a plasma discharge electrode 16 for generating an electric discharge to the reaction space 6. The method comprises arranging the one or more substrates 13 into the reaction chamber 50 opposite the plasma discharge electrode 16, supplying the at least first precursor A and second precursor B into the reaction space 6 via one or more gas inlets 8 for subjecting the surface of the substrate to successive surface reactions of the precursors A, B and discharging the at least first precursor A and second precursor B from the reaction space 6 via one or more gas outlets 12. The method further comprises supplying the at least first precursor A and second precursor B into the reaction space 6 having an grounded grid sheet 21 provided within the reaction space 6 between the plasma discharge electrode 16 and the substrate 13, the grid sheet 21 having openings 23 through the grid sheet 21 and being arranged opposite the plasma discharge electrode 16. Plasma discharge is further generated with the plasma discharge electrode 16 in the reaction space 6 between the plasma discharge electrode 16 and the grid sheet 21 for forming active precursor radicals from the first precursor A. At least a portion of the formed active precursor radicals are passed through the openings 23 in the grid sheet 21 into the reaction space 6 between the substrate 13 and grid sheet 21.

In one embodiment the method comprises supplying the at least first precursor A and second precursor B into the reaction space 6 of the reaction chamber 50 on both sides of the grounded grid sheet 21. The plasma discharge electrode 16 is arranged in connection with a first wall surface 4 of the reaction chamber 50 and the grid sheet 21 being arranged into the reaction space 6 between and opposite the plasma discharge electrode 16 and the substrate 13 at a first distance 56 from the first wall surface 4 and at a second distance 57 from the substrate 13.

The method may further comprise adjusting the adjusting the first distance 56 between the grid sheet 21 and the first wall surface 4 or adjusting the second distance 57 between the grid sheet 21 and the substrate 13. Alternatively the present invention may comprise adjusting the first distance 56 between the grid sheet 21 and the first wall surface 4 and second distance 57 between the grid sheet 21 and the substrate 13.

In another embodiment the method comprises supplying the at least first precursor A and second precursor B into the reaction space 6 via the one or more gas inlets 8, discharging the at least first precursor A and second precursor B from the reaction space 6 via the one or more gas outlets 12 provided to opposite the one or more gas inlets 8, and generating plasma discharge with the plasma discharge electrode 16 provided in connection with the first wall surface 4 extending between the one or more gas inlets 8 and one or more gas outlets 12.

In an alternative embodiment the method comprises supplying the at least first precursor A and second precursor B into the reaction space 6 via the one or more gas inlets 8 provided to a third wall surface 7 of the reaction chamber 50, discharging the at least first precursor A and second precursor B from the reaction space 6 via the one or more gas outlets 12 provided to a fourth wall surface 9 of the reaction chamber 50 opposite the third wall surface 7, and generating plasma discharge with the plasma discharge electrode 16 provided in connection with the first wall surface 4 extending between the third walls surface 7 and fourth wall surface 9.

In one embodiment the method comprises supplying the first precursor A in a pulsed manner and generating the plasma discharge during the supply pulse of the first precursor A, and supplying the second precursor B in a pulsed manner. In an alternative embodiment the method comprises supplying the first precursor A continuously and supplying the second precursor B in a pulsed manner, and generating the plasma discharge between the supply pulses of the second precursor B for forming active precursor radicals from the first precursor A. In a yet alternative embodiment the method comprises supplying the first precursor A and a purge gas P continuously and supplying the second precursor B in a pulsed manner into the reaction space 6, and generating the plasma discharge between the supply pulses of the second precursor B for forming active precursor radicals from the first precursor A.

In the method according to the present invention the supply of the precursors A, B into the reaction space 6 may be carried out in more than one different ways. In one embodiment the method comprises supplying the first precursor A into the reaction space 6 via one or more first gas inlets and supplying the second precursor B via one or more second gas inlets into the reaction space 6. Accordingly, in this embodiment the precursors A, B are supplied into the reaction space 6 via separate gas inlets. In an alternative embodiment the method comprises supplying the first precursor A into the reaction space 6 via one or more first gas inlets, supplying the second precursor B via one or more second gas inlets into the reaction space 6 and supplying purge gas into the reaction space 6 via one or more third gas inlets. Accordingly, in this embodiment the precursors A, B and purge gas P are supplied into the reaction space 6 via separate gas inlets. In another alternative embodiment the method comprises supplying the first precursor A and the second precursor B via the one or more common gas inlets 8 into the reaction space 6, or alternatively supplying the first precursor, the second precursor and a purge gas via the one or more common gas inlets 8 into the reaction space 6.

It will be obvious to a person skilled in the art that, as the technology advances, the inventive concept can be implemented in various ways. The invention and its embodiments are not limited to the examples described above but may vary within the scope of the claims.

1.-18. (canceled)

19. An apparatus for subjecting a surface of a substrate to successive surface reactions of at least a first precursor and a second precursor according to the principles of atomic layer deposition, said apparatus comprising:
a reaction chamber having wall surfaces defining a reaction space inside the reaction chamber;
one or more gas inlets for supplying the at least first precursor and second precursor into the reaction space;
one or more gas outlets; and
a plasma discharge electrode for generating an electric discharge to the reaction space for forming active precursor radicals,
wherein:
the apparatus further comprises a grid sheet provided in the reaction space and having openings, the openings arranged to pass towards the substrate active precursor radicals generated by the electric discharge;
the grid sheet is connected to ground potential;
the grid sheet is arranged within the reaction space opposite the plasma discharge electrode.

20. The apparatus according to claim 19, wherein the plasma discharge electrode is arranged in connection with a first wall surface of the reaction chamber and the grid sheet is arranged into the reaction space opposite the plasma discharge electrode and at a first distance from the first wall surface and at a second distance from a wall surface opposite the first wall surface.

21. The apparatus according to claim 19, wherein the one or more gas inlets are arranged to supply the at least first precursor and second precursor on both sides of the grid sheet.

22. The apparatus according to claim 19, wherein the apparatus comprises:
a substrate support for supporting the substrate in the reaction chamber; or
a second wall surface opposite the first wall surface is provided as a substrate support for supporting the substrate in the reaction chamber.

23. The apparatus according to claim 19, wherein:
the one or more gas inlets and the one or more gas outlets are provided on opposite sides of the reaction space for forming a cross flow reaction chamber in which the at least first precursor and second precursor flow through the reaction space from the one or more gas inlets to the one or more gas outlets; or
the one or more gas outlets are provided opposite the one or more gas inlets for forming a cross flow reaction chamber in which the at least first precursor and second precursor flow linearly through the reaction space from the one or more gas inlets to the one or more gas outlets; or
the one or more gas inlets are provided to a third wall surface of the reaction chamber and the one or more gas outlets are provided to a fourth wall surface of the reaction chamber opposite the third wall surface for forming a cross flow reaction chamber in which the at least first precursor and second precursor flow through the reaction space from the one or more gas inlets to the one or more gas outlets.

24. The apparatus according claim 19, wherein:
the one or more gas inlets are provided to a third wall surface of the reaction chamber adjacent the first wall surface such that the at least first precursor and second precursor pass the plasma discharge electrode when flowing from the one or more gas inlets to the one or more gas outlets; or
the one or more gas inlets are provided to a third wall surface of the reaction chamber, the one more gas outlets are provided to a fourth wall surface opposite the third wall surface, the first wall surface of the reaction chamber being adjacent the third wall surface and the fourth wall surface such that the at least first precursor and second precursor pass the plasma discharge electrode when flowing from the one or more gas inlets to the one or more gas outlets; or
the one or more gas inlets are provided to a third wall surface of the reaction chamber, the one more gas outlets are provided to a fourth wall surface opposite the third wall surface, a substrate support is provided in connection with a second wall surface opposite the first wall surface, the first wall surface of the reaction chamber being adjacent the third wall surface and the fourth wall surface such that the at least first precursor and second precursor pass the plasma discharge electrode and between the first wall surface and second wall surface when flowing from the one or more gas inlets to the one or more gas outlets.

25. The apparatus according to claim 19, wherein:
the apparatus comprises one or more first gas inlets for supplying the first precursor into the reaction space and one or more second gas inlets for supplying the second precursor into the reaction space; or
the apparatus comprises a first precursor conduit and a second precursor conduit arranged in fluid connection with the one or more gas inlets for supplying both the first and second precursor into the reaction space together via the one or more gas inlets.

26. The apparatus according to claim 19, wherein:
the grid sheet is arranged opposite the plasma discharge electrode and at the first distance from the plasma discharge electrode; or
the grid sheet is arranged opposite the substrate support and at the second distance from the substrate support; or
the substrate support is arranged opposite the plasma discharge electrode, the grid sheet is arranged opposite the plasma discharge electrode at the first distance from the plasma discharge electrode, and the grid sheet is arranged opposite the substrate support at the second distance from the substrate support.

27. The apparatus according to claim 19, wherein:
the apparatus comprises an adjustment arrangement for adjusting the first distance between the grid sheet and the first wall surface; or
the apparatus comprises an adjustment arrangement for adjusting the second distance between the grid sheet and the wall surface opposite the first wall surface or the substrate support; or
the apparatus comprises an adjustment arrangement for adjusting the first distance between the grid sheet and the first wall surface and second distance between the wall surface opposite the first wall surface.

28. The apparatus according to claim 19, wherein the grid sheet comprises:
a metal plate comprising openings; or
a metal mesh comprising openings.

29. The apparatus according to claim 19, wherein the grid sheet is arranged:
in front of the one or more gas inlets and to extend from the one or more gas inlets for receiving the at least first precursor and second precursor on both sides of the grid sheet; or
to extend from the one or more gas inlets for receiving the at least first precursor and second precursor on both sides of the grid sheet; or
to extend between the one or more gas inlets and the one or more gas outlets for receiving the at least first precursor and second precursor on both sides of the grid sheet; or
at a third distance from the one or more gas inlets and to extend between the one or more gas inlets and the one or more gas outlets for receiving the at least first precursor and second precursor on both sides of the grid sheet.

30. The apparatus according to claim 19, wherein the apparatus further comprises:
a precursor system arranged to supply the first precursor continuously and the second precursor in pulsed manner into the reaction chamber via the one or more gas inlets into the reaction space;
a precursor system arranged to supply the first precursor and inert purge gas continuously and the second precursor in pulsed manner into the reaction chamber via the one or more gas inlets into the reaction space;
a precursor system arranged to supply the first precursor continuously and the second precursor in pulsed manner into the reaction chamber via the one or more gas inlets into the reaction space, the precursor system is further arranged to activate the plasma discharge electrode between the supply pulses of the second precursor for forming active precursor radicals from the first precursor; or
a precursor system arranged to supply the first precursor and inert purge gas continuously and the second precursor in pulsed manner into the reaction chamber via the one or more gas inlets into the reaction space, the precursor system is further arranged to active the plasma discharge electrode between the supply pulses of the second precursor for forming radicals from the first precursor.

31. A method for subjecting a surface of a substrate to successive surface reactions of at least a first precursor and a second precursor according to the principles of atomic layer deposition in a reaction chamber having wall surfaces defining a reaction space inside the reaction chamber, the reaction chamber further comprising a plasma discharge electrode for generating an electric discharge to the reaction space, said method comprising:
arranging the substrate into the reaction chamber opposite the plasma discharge electrode;
supplying the at least first precursor and second precursor into the reaction space via one or more gas inlets;
discharging the at least first precursor and second precursor from the reaction space via one or more gas outlets,
wherein the method further comprises:
supplying the at least first precursor and second precursor into the reaction space having a grounded grid sheet provided within the reaction space between the plasma discharge electrode and the substrate, the grid sheet having openings and being arranged opposite the plasma discharge electrode;
generating plasma discharge with the plasma discharge electrode in the reaction space between the plasma discharge electrode and the grid sheet for forming active precursor radicals from the first precursor; and
passing at least a portion of the active precursor radicals through the openings in the grid sheet into the reaction space between the substrate and grid sheet.

32. The method according to claim 31, wherein the method comprises supplying the at least first precursor and second precursor into the reaction space of the reaction chamber on both sides of the grounded grid sheet, the plasma discharge electrode being arranged in connection with a first wall surface of the reaction chamber and the grid sheet being arranged into the reaction space between and opposite the plasma discharge electrode and the substrate at a first distance from the first wall surface and at a second distance from the substrate.

33. The method according to claim 31, wherein the method comprises:
supplying the at least first precursor and second precursor into the reaction space via the one or more gas inlets, discharging the at least first precursor and second precursor from the reaction space via the one or more gas outlets provided to opposite the one or more gas inlets, and generating plasma discharge with the plasma discharge electrode provided in connection with the first wall surface extending between the one or more gas inlets and one or more gas outlets; or
supplying the at least first precursor and second precursor into the reaction space via the one or more gas inlets provided to a third wall surface of the reaction chamber, discharging the at least first precursor and second precursor from the reaction space via the one or more gas outlets provided to a fourth wall surface of the reaction chamber opposite the third wall surface, and generating plasma discharge with the plasma discharge electrode provided in connection with the first wall surface extending between the third wall surface and fourth wall surface.

34. The method according to claim 31, wherein the method comprises:
supplying the first precursor in a pulsed manner and generating the plasma discharge during the supply pulse of the first precursor, and supplying the second precursor in a pulsed manner; or
supplying the first precursor continuously and supplying the second precursor in a pulsed manner, and generating the plasma discharge between the supply pulses of the second precursor; or
supplying the first precursor and a purge gas continuously and supplying the second precursor in a pulsed manner, and generating the plasma discharge between the supply pulses of the second precursor.

35. The method according to claim 31, wherein the method comprises:
supplying the first precursor into the reaction space via one or more first gas inlets and supplying the second precursor via one or more second gas inlets into the reaction space; or
supplying the first precursor into the reaction space via one or more first gas inlets, supplying the second precursor via one or more second gas inlets into the reaction space, supplying purge gas into the reaction space via one or more third gas inlets; or
supplying the first precursor and the second precursor via the one or more common gas inlets into the reaction space; or
supplying the first precursor, the second precursor and a purge gas via the one or more common gas inlets into the reaction space.

36. The method according to claim 31, wherein the method comprises:
adjusting the adjusting the first distance between the grid sheet and the first wall surface; or
adjusting the second distance between the grid sheet and the substrate; or
adjusting the first distance between the grid sheet and the first wall surface and second distance between the grid sheet and the substrate.
